(19) United States
(12) Patent Application Publication
(10) Pub. No.: US 2008/0074922 A1
(43) Pub. Date: Mar. 27, 2008

(54) 2-TRANSISTOR NONVOLATILE MEMORY CELL

(75) Inventors: I-Ming Chang, Hsinchu City (TW); Chia-Ta Hsieh, Tainan City (TW); Hsiang-Tai Lu, Hsinchu City (TW)

Correspondence Address: THOMAS, KAYDEN, HORSTEMEYER & RISLEY LLP, 600 GALLERIA PARKWAY, 15TH FLOOR, ATLANTA, GA, 30339, US

(73) Assignee: TAIWAN SEMICONDUCTOR MANUFACTURING CO., LTD., Hsin-Chu (TW)

(21) Appl. No.: 11/533,791

(22) Filed: Sep. 21, 2006

(51) Int. Cl. G11C 16/04

(52) U.S. Cl. 365/185.05

(57) ABSTRACT

A 2-transistor (2T) memory cell comprising a first transistor and a second transistor. The first and second transistors respectively have a source and a drain separated apart by a channel thereof, a floating gate over the channel near the source side, and a control gate over the floating gate and the channel near the drain side. The sources, floating gates, and control gates of the first and second transistors are respectively mutually connected. In addition, driving capability of the second transistor is substantially larger than that of the first transistor.

### BACKGROUND OF THE INVENTION

1. Field of the Invention

The invention relates to nonvolatile memory cells and, in particular, to nonvolatile memory cells each having two transistors.

2. Description of the Related Art

FIG. 1A shows a layout of a conventional 2-transistor (2T) nonvolatile memory cell. The 2T nonvolatile memory cell 100 comprises a first transistor 110 and a second transistor 120. FIG. 1B is a cross section of the first and second transistors in the 2T nonvolatile memory cell in FIG. 1A. As shown in FIGS. 1A and 1B, the first and second transistors respectively have a source 160 and a drain 150 separated apart by a channel 170 thereof, a floating gate 140 over the channel 170 near the source side, and a control gate 130 over the floating gate 140 and the channel 170 near the drain side. In FIG. 1A, the sources 160, floating gates 140, and control gates 130 of the first and second transistors are respectively mutually connected. The drains 150 of the first and second transistors are isolated by an isolation region 180 and electrically connected to different nodes in a circuit. The first and second transistors are identical in respect with all physical aspects, such as channel width, channel length, gate oxide thickness, implantation dosage, etc.

In the conventional nonvolatile 2T memory cell, one transistor performs mainly memory programming and the other mainly memory read. Every time during memory programming, traps are generated and accumulated on a program channel by source-side hot electron injection. After erase-and-program cycles, the accumulated traps reduce program efficiency such that the conventional nonvolatile 2T memory cell suffers from weak program.

### BRIEF SUMMARY OF THE INVENTION

An embodiment of a 2-transistor (2T) memory cell comprises a first transistor and a second transistor. The first and second transistors respectively have a source and a drain separated apart by a channel thereof, a floating gate over the channel near the source side, and a control gate over the floating gate and the channel near the drain side. The sources, floating gates, and control gates of the first and second transistors are respectively mutually connected. In addition, driving capability of the second transistor is substantially higher than that of the first transistor.

The invention provides a memory cell with two transistors having different driving capabilities. The transistor with stronger driving capability is mainly for memory programming such that endurance of the memory cell is improved.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A shows a layout of a conventional 2-transistor (2T) nonvolatile memory cell;

FIG. 1B is a cross section of the first and second transistors in the 2T nonvolatile memory cell in FIG. 1A;

FIG. 2A shows a layout of a 2-transistor (2T) nonvolatile memory cell according to an embodiment of the invention;

FIG. 2B is a cross section of the first and second transistors in the 2T nonvolatile memory cell in FIG. 2A;

FIG. 2C illustrates an electric schematic showing the connection of two transistors in the 2-T nonvolatile memory cell of FIG. 2A;

FIG. 3 shows experimental results of endurance testing of the 2T nonvolatile memory cell;

FIGS. 4-8 show layouts of 2-transistor (2T) nonvolatile memory cells according to embodiments of the invention; and

FIG. 9 exemplifies a cross section of the first and second transistors in the 2T nonvolatile memory cell according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

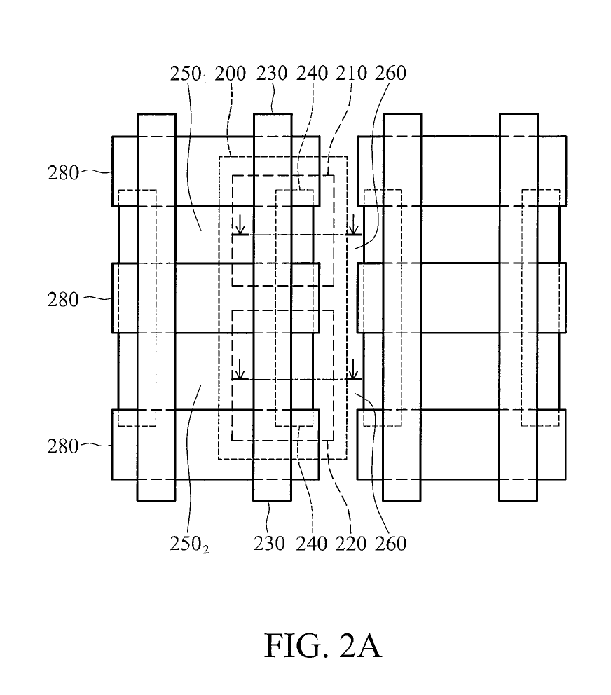

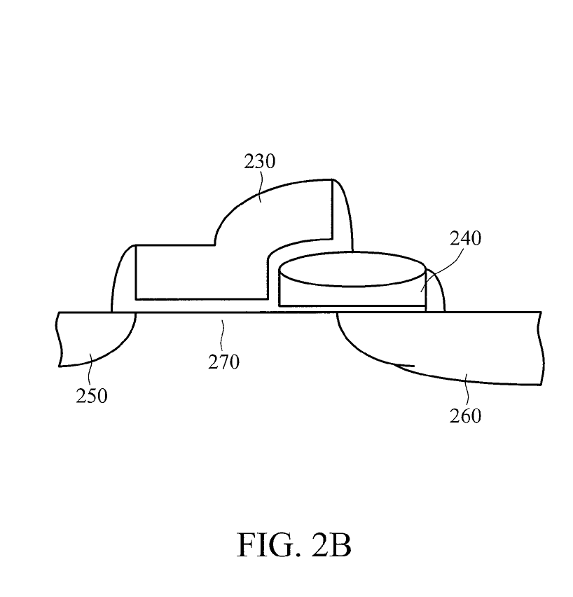

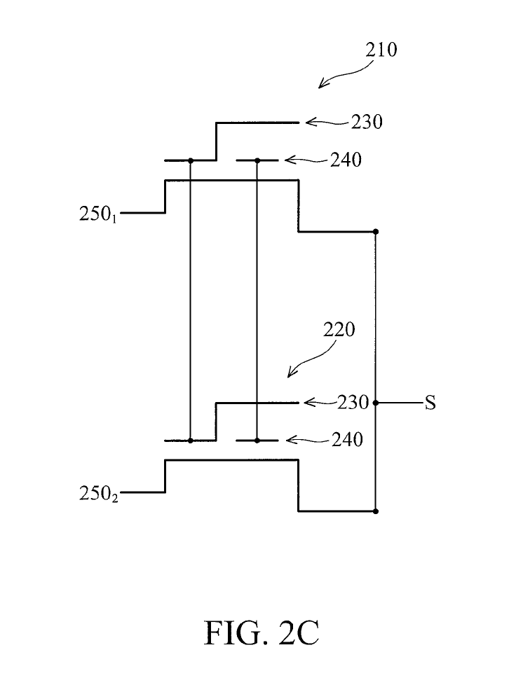

FIG. 2A shows a layout with a 2-transistor (2T) nonvolatile memory cell according to an embodiment of the invention. The 2T nonvolatile memory cell 200 comprises a first transistor 210 and a second transistor 220. FIG. 2B is a cross section of the first and second transistors in the 2T nonvolatile memory cell in FIG. 2A. FIG. 2C illustrates an electric schematic showing the connection of two transistors in the 2-T nonvolatile memory cell of FIG. 2A. As shown in FIGS. 2A, 2B and 2C, the first and second transistors are alike, each having a source 260 and a drain (250₁ or 250₂) separated apart by a channel 270 thereof, a floating gate 240 over the channel 270 near the source side, and a control gate 230 over the floating gate 240 and the channel 270 near the drain side. As shown in FIGS. 2A and 2C, the sources 260, floating gates 240, and control gates 230 of the first and second transistors are respectively mutually connected. Drain 250₁ of the first transistor and drain 250₂ of the second transistor are isolated by an isolation region 280, which can be a local oxidation of silicon (LOCOS) structure, a shallow trench isolation (STI) structure, or the like. Preferably, the isolation region is a shallow trench isolation (STI) structure to provide a planarized surface that eases the formation and patterning of other layers stacking thereover.

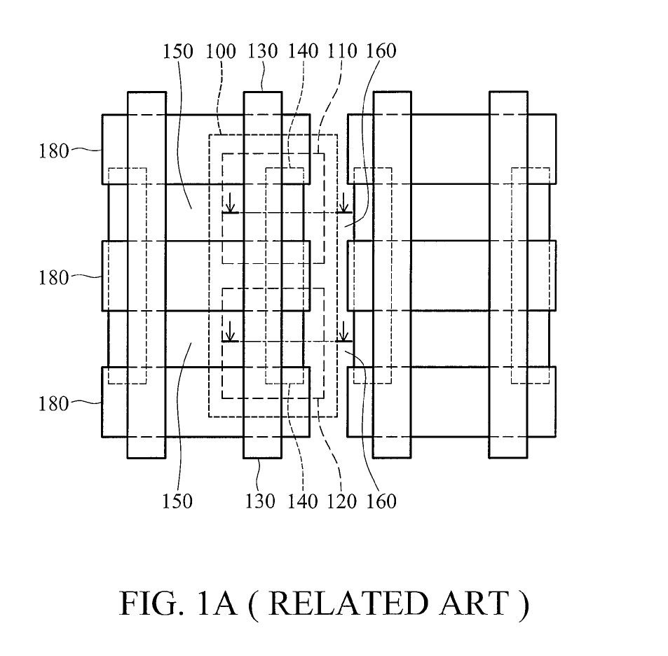

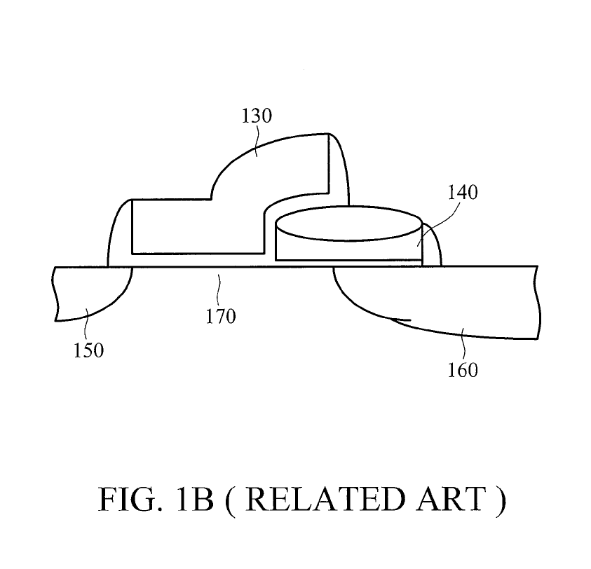

Unlike the first transistor 110 and the second transistor 120 in FIG. 1A, which have the same channel width, the first transistor 210 and the second transistor 220 in FIG. 2A have different channel widths. As shown in FIG. 2A, the second transistor 220 has a channel width larger than the first transistor 210, causing that the driving capability of the second transistor 220 is substantially higher than that of the first transistor 210 and that the second transistor 220 is more suitable for performing memory programming. Since the first transistor 210 and the second transistor 220 respectively perform memory read and memory programming, the generated traps in the second transistor 220 have no impact on read current of the first transistor 210. Preferably, channel widths of the first and second transistors are respectively 0.5 and 0.6 μm for 0.25 μm generation. For 0.18 μm generation, channel widths of the first and second transistors are preferably 0.22˜0.3 μm and 0.3˜0.6 μm, respectively.

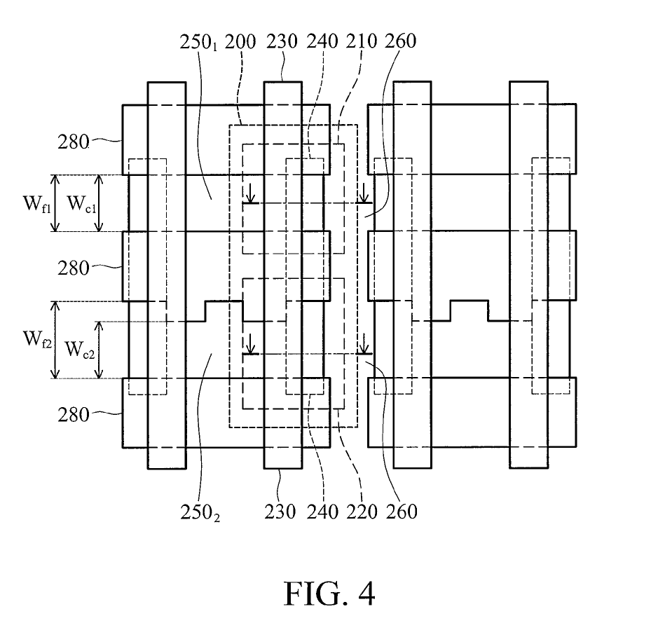

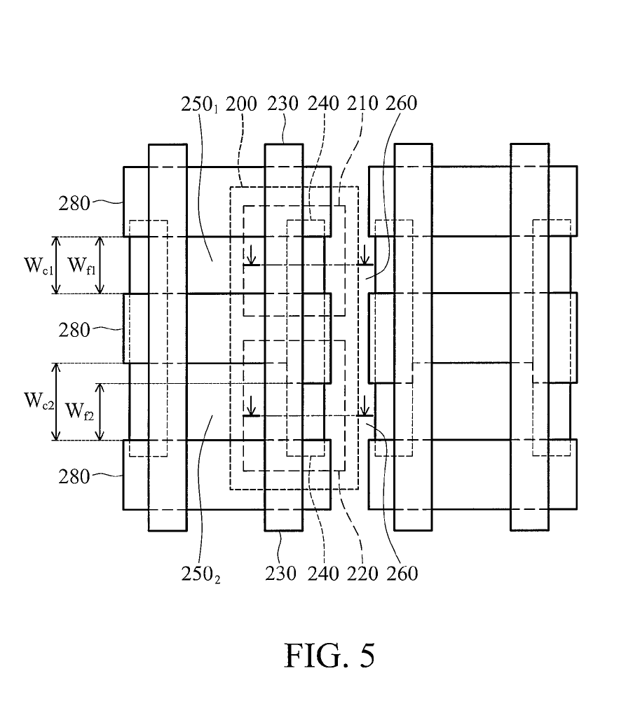

To increase driving capability of the second transistor 220 beyond that of the first transistor 210, several methods can be used. The preferable way for differentiating the driving capabilities of the transistors is through modification of photo mask(s) that is used during memory fabrication. For example, effective channel width of the first transistor 210 can be smaller than the second transistor 220. Channel widths of both the floating gate 240 and the control gate 230 of the first transistor 210 can be narrower than those of the second transistor 220, as shown in FIG. 2A. Channel width of the floating gate 240 of the first transistor 210, W_{f1}, can be narrower than that of the second transistor 220, W_{f2}, while the channel width under the control gate of the first transistor 210, W_{c1}, remains the same with that of the second transistor 220, W_{c2}, as shown in FIG. 4, where W_{f2}>W_{f1} and W_{c2}=W_{c1}. The channel width under the control gate 230 of the first transistor 210 can be narrower than that of the second transistor 220 while channel widths of the floating gates of the first transistor 210 and the second transistor 220 are the same, as shown in FIG. 5, where W_{f2}=W_{f1} and W_{c2}>W₁.

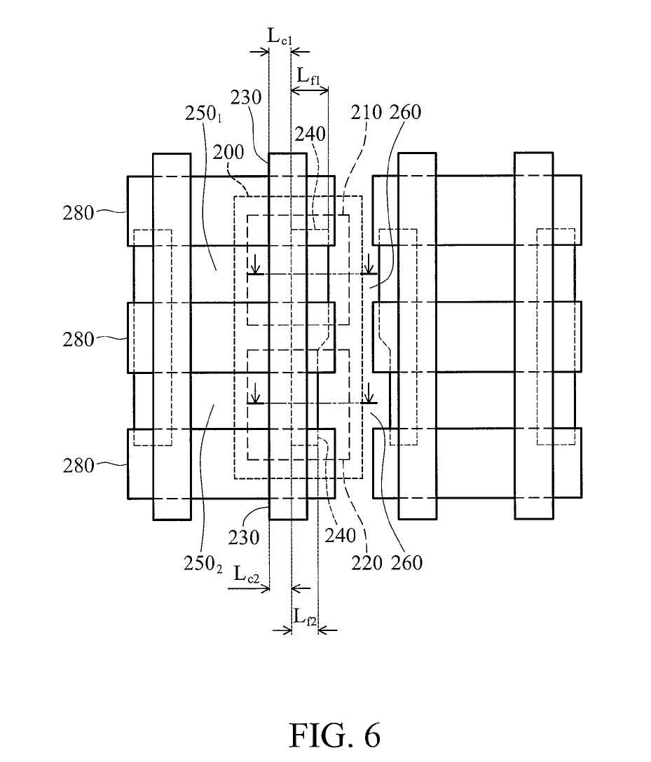

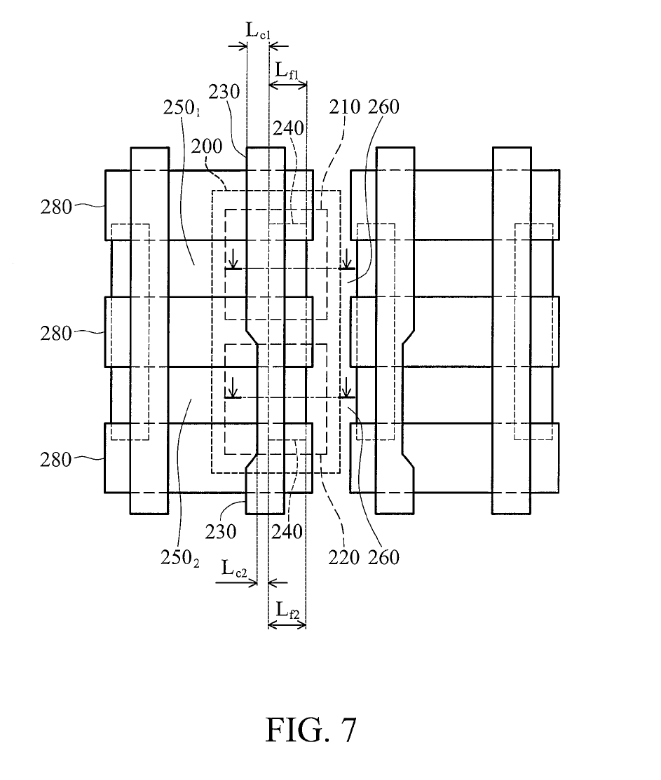

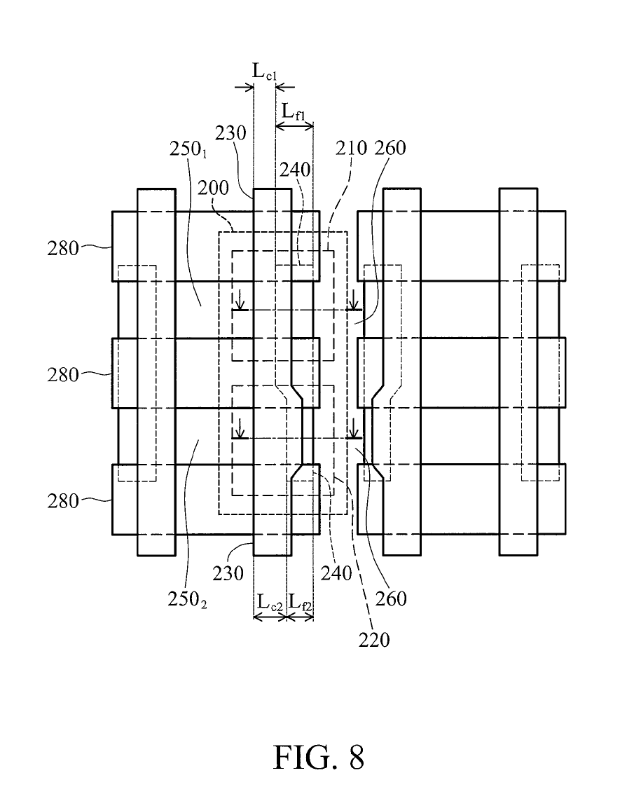

Furthermore, beside the channel widths aforementioned, channel lengths can be modified to differentiate the driving capabilities of the transistors. FIG. 6 illustrates that while the effective channel widths of the first transistor 210 and the second transistor 220 are the same and the channel lengths under the control gates of the first transistor 210 and the second transistor 220 (L_{c1} and L_{c2}) are the same, the channel length under the floating gate of the second transistor 220, L_{f2}, is shorter than of the first transistor 210, L_{f1}, causing the driving capacity of the second transistor 220 larger than that of the first transistor 210. FIG. 7 illustrates that while the effective channel widths of the first transistor 210 and the second transistor 220 are the same and the channel lengths under the floating gates of the first transistor 210 and the second transistor 220 (L_{f1} and L_{f2}) are the same, the channel length under the control gate of the second transistor 220, L_{c2}, is shorter than of the first transistor 210, L_{c1}, causing the driving capacity of the second transistor 220 larger than that of the first transistor 210. Since the driving capacity for the floating gate per unit area is generally weaker than that for the control gate per unit area, the second transistor 220 has a larger driving capacity than the first transistor 210 does if L_{c2}>L_{c1} and L_{f2}<L_{f1} while (L_{c}+L_{f1})=(L_{c2}+L_{f2}), as shown in FIG. 8.

Even though each of FIGS. 2A, and 4-8 illustrates either channel width modification or channel length modification to the second transistor 220, a person skilled in the art will appreciate that combining channel width modification with channel length modification can also change driving ability of a transistor and can become another option to differentiate the driving capabilities of the first and second transistors 210 and 220.

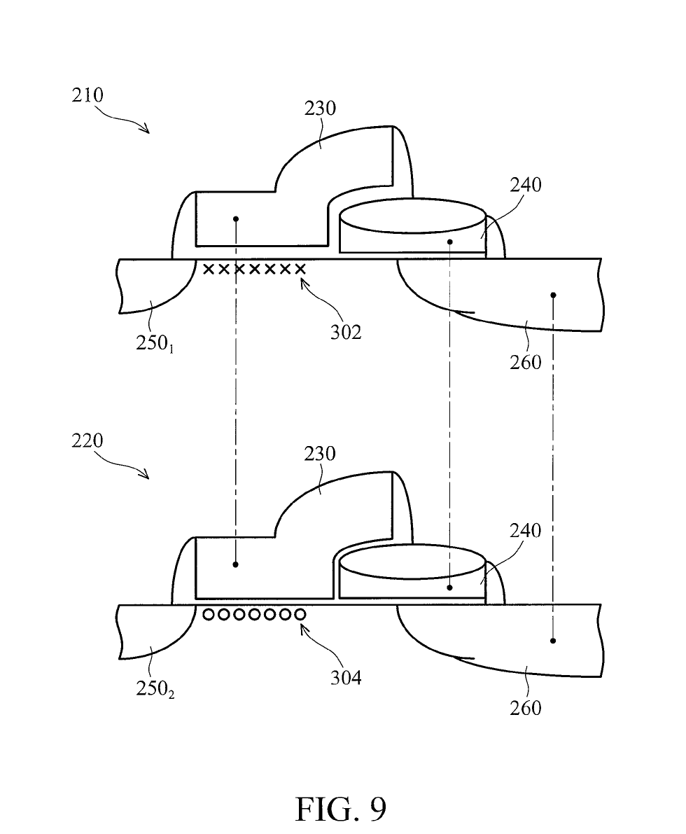

The first transistor 210 and the second transistor 220 may have the same channel width and the same channel length, but differ in layer thickness or impurity dosage concentration such that the second transistor 220 has a higher driving capacity than the first transistor 210 does. For example, the threshold voltage of the first transistor 210 may be higher than the second transistor 220, and thus, even if the first transistor 210 and the second transistor 220 have the same layout dimension, the second transistor 220 has a higher driving capacity than the first transistor 210 does. Threshold voltage difference can be made by differentiating gate oxide thickness, Vt implantation dosage, for example. FIG. 9 illustrates, in the top, the cross section of the first transistor 210 and, in the bottom, the cross section of the first transistor 220. As shown in FIG. 9, the gate oxide thickness of the control gate in the first transistor 210 is thicker than that of the second transistor 220, such that, if other physical features remain the same, the threshold voltage of the first transistor 210 is higher. Threshold voltage of a transistor can be also influenced by impurity dosage concentration under a gate oxide. For example, as shown in FIG. 9, if the impurity concentration in area 302 under the control gate of the first transistor 210 is different from that in the area 304 under the control gate of the second transistor 220, and all other physical features of the first transistor 210 are the same with those of the second transistor 220, the thresholds of the first transistor 210 and the second transistor 220 become different. If they are N-type transistors and area 302 has P type impurity dosage concentration more than area 304, the threshold voltage of the first transistor 210 is higher.

Differentiating the driving capacities of the first and second transistors by ways of means other than mask modification requires at least one additional mask and additional related processes, causing considerably-high cost.

Embodiments of the present invention disclose a 2T nonvolatile memory cell with two transistors having different driving capacities. A plurality of the 2T nonvolatile memory cells according to the invention can construct a memory array arranged in columns and rows. Memory cells in a memory array having one 2T nonvolatile memory cell according to the invention need not to be identical. Based on reliability requirements, portion of a memory array may have 2T nonvolatile memory cells each having two identical transistors, and another portion of the memory array may have 2T nonvolatile memory cells each having two transistors with different driving capacities. FIG. 6 embodies this concept, and has, in the center, a 2T nonvolatile memory cell 200 including the transistors 210 and 220 with different driving capacities and, in the left, another 2T nonvolatile memory cell including two identical transistors.

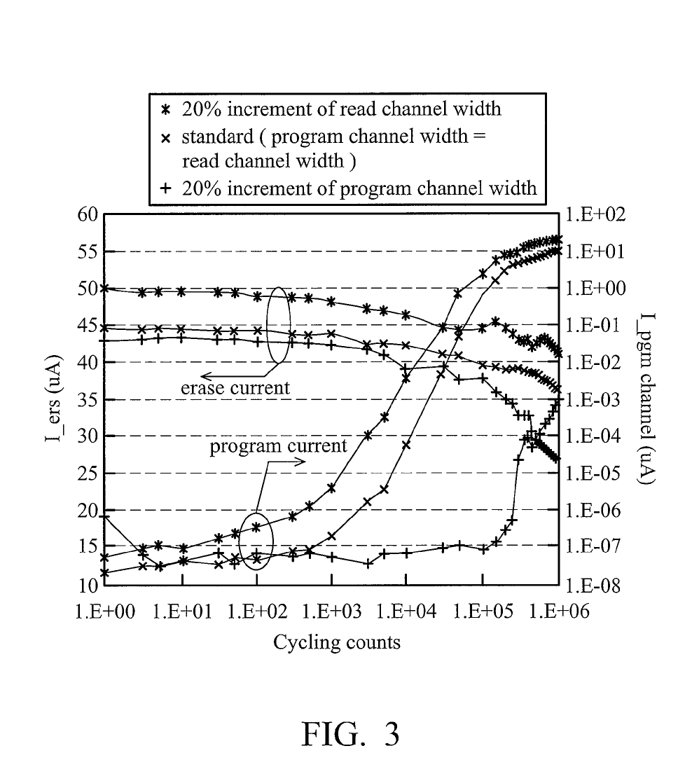

FIG. 3 shows experimental results of endurance testing of the 2T nonvolatile memory cell. 3 different 2T nonvolatile memory cells are compared. One is the standard, conventional 2T nonvolatile memory cell, having two identical transistors for reading and programming, respectively. Another is a programming-enhanced 2T nonvolatile memory cell in which the channel width for the transistor for programming is 20% widened in comparison with that for one transistor in the standard 2T nonvolatile memory cell. The other is a reading-enhanced 2T nonvolatile memory cell in which the channel width of the transistor for reading is widened 20% in comparison with that for one transistor in the standard 2T nonvolatile memory cell. The endurance tests are carried out with a programming current about 1 μA. As shown in FIG. 3, programming current of the standard (Std) 2T nonvolatile memory cell with identical transistors is about 10 μA after 1000K program and erase cycles, and the 2T nonvolatile memory cell with a widen read transistor is slightly higher. However, program current of the 2T nonvolatile memory cell with a widened program transistor (PGM+20%) according to an embodiment of the invention is lower than 10⁻³ uA(1 nA) after 1000K program and erase cycles. It can be found from FIG. 3 that endurance of the 2T nonvolatile memory cell with a widened program transistor (PGM+20%) according to an embodiment of the invention is increased by 10 fold.

The invention provides a memory cell with two transistors having different driving capabilities. The transistor with stronger driving capability is used mainly for memory programming such that endurance of the memory cell is improved.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A 2-transistor (2T) nonvolatile memory cell, comprising:
a first transistor having a source and a drain separated apart by a channel thereof, a floating gate over the channel near the source side, and a control gate over the floating gate and the channel near the drain side; and
a second transistor having a source and a drain separated apart by a channel thereof, a floating gate over the channel near the source side, and a control gate over the floating gate and the channel near the drain side;
wherein the sources, floating gates, and control gates of the first and second transistors are respectively mutually connected and driving capability of the first transistor is substantially lower than that of the second transistor.

2. The 2-transistor (2T) nonvolatile memory cell as claimed in claim 1, wherein the first transistor is mainly used for memory read and the second transistor mainly for memory programming.

3. The 2-transistor (2T) nonvolatile memory cell as claimed in claim 1, wherein channel of the second transistor is substantially wider than that of the first transistor.

4. The 2-transistor (2T) nonvolatile memory cell as claimed in claim 1, wherein the channel under the floating gate of the first transistor is narrower than that under the floating gate of the second transistor.

5. The 2-transistor (2T) nonvolatile memory cell as claimed in claim 1, wherein channel under the control gate of the first transistor is narrower than that under the control gate of the second transistor.

6. The 2-transistor (2T) nonvolatile memory cell as claimed in claim 1, wherein a gate oxide under the control gate of the first transistor is thicker than that of the second transistor.

7. The 2-transistor (2T) nonvolatile memory cell as claimed in claim 1, wherein threshold voltage of the first transistor is higher than that of the second transistor.

8. The 2-transistor (2T) nonvolatile memory cell as claimed in claim 1, wherein channel widths of the first and second transistors are respectively 0.5 and 0.6 μm.

9. The 2-transistor (2T) nonvolatile memory cell as claimed in claim 1, wherein channel widths of the first and second transistors respectively ranges from 0.22 to 0.3 μm and 0.3 to 0.6 μm.

10. The 2-transistor (2T) nonvolatile memory cell as claimed in claim 1, wherein the channel under the floating gate of the first transistor is longer than that of the second transistor.

11. The 2-transistor (2T) nonvolatile memory cell as claimed in claim 1, wherein the channel under the control gate of the first transistor is longer than that of the second transistor.

12. A memory array comprising a plurality of 2-transistor (2T) nonvolatile memory cells, at least one of the 2T nonvolatile memory cells comprising:
a first transistor having a source and a drain separated apart by a channel thereof, a floating gate over the channel near the source side, and a control gate over the floating gate and the channel near the drain side; and
a second transistor having a source and a drain separated apart by a channel thereof, a floating gate over the channel near the source side, and a control gate over the floating gate and the channel near the drain side;
wherein the sources, floating gates, and control gates of the first and second transistors are respectively mutually connected and driving capability of the first transistor is substantially lower than that of the second transistor.

13. The memory array as claimed in claim 10, wherein at least another of the 2T nonvolatile memory cells comprises two identical transistors.

14. The memory array as claimed in claim 10, wherein the first transistor is mainly used for memory read and the second transistor mainly for memory programming.

15. The memory array as claimed in claim 10, wherein channel of the first transistor is substantially narrower than that of the second transistor.

16. The memory array as claimed in claim 10, wherein the channel under the floating gate of the first transistor is narrower than that of the second transistor.

17. The memory array as claimed in claim 10, wherein the channel under the control gate of the first transistor is narrower than that of the second transistor.

18. The memory array as claimed in claim 10, wherein a gate oxide under the control gate of the first transistor is thicker than that of the second transistor.

19. The memory array as claimed in claim 10, wherein threshold voltage of the first transistor is higher than that of the second transistor.

20. The memory as claimed in claim 10, wherein channel widths of the first and second transistors respectively ranges from 0.22 to 0.3 μm and 0.3 to 0.6 μm.
